(19) United States
(12) Patent Application Publication
(10) Pub. No.: US 2025/0116814 A1
(43) Pub. Date: Apr. 10, 2025

(54) LASER REDUNDANCY DEVICE

(71) Applicant: Lumentum Operations LLC, San Jose, CA (US)

(72) Inventors: Cailin WEI, San Jose, CA (US); Jihua DU, San Jose, CA (US); Prasad YALAMANCHILI, San Jose, CA (US); Liang ZHAO, Sunnyvale, CA (US); Hao XU, San Jose, CA (US)

(21) Appl. No.: 18/525,564

(22) Filed: Nov. 30, 2023

Related U.S. Application Data
(60) Provisional application No. 63/589,087, filed on Oct. 10, 2023.

(51) Int. Cl. G02B 6/26; G02B 6/38; G02B 6/42

(52) U.S. Cl. CPC G02B 6/262; G02B 6/3885; G02B 6/4206; G02B 6/425

(57) ABSTRACT

A laser redundancy device includes a plurality of lasers and a PLC that includes a plurality of input waveguides, a plurality of first couplers, a plurality of intermediate waveguides, a plurality of second couplers, and a plurality of output waveguides. Each first coupler includes a plurality of first input arms and a plurality of first output arms. Each second coupler includes a plurality of second input arms and a plurality of second output arms. Each first coupler is connected to: two or more input waveguides via the plurality of first input arms, and the plurality of second couplers via the plurality of first output arms, two or more intermediate waveguides, and respective second input arms of the plurality of second couplers. Each second coupler is connected to two or more output waveguides via the plurality of second output arms.

### CROSS-REFERENCE TO RELATED APPLICATION

This patent application claims priority to U.S. Patent Application No. 63/589,087, filed on Oct. 10, 2023, and entitled “LASER ARRAY COUPLED TO FIBER ARRAY WITH BUILT-IN REDUNDANT POWER.” The disclosure of the prior application is considered part of and is incorporated by reference into this patent application.

### TECHNICAL FIELD

The present disclosure relates generally to a laser redundancy device and to a laser redundancy device that includes a planar lightwave circuit (PLC).

### BACKGROUND

An optical system, such as an optical amplifier, can include multiple lasers (e.g., pump lasers) to provide multiple laser beams for use in the optical system.

### SUMMARY

In some implementations, a laser redundancy device comprising: a plurality of lasers disposed on a common substrate; and a PLC that includes a plurality of input waveguides, a plurality of first couplers, a plurality of intermediate waveguides, a plurality of second couplers, and a plurality of output waveguides, wherein: each first coupler, of the plurality of first couplers, includes a plurality of first input arms and a plurality of first output arms, each second coupler, of the plurality of second couplers, includes a plurality of second input arms and a plurality of second output arms, each first coupler is connected to: two or more input waveguides, of the plurality of input waveguides, via the plurality of first input arms of the first coupler, and the plurality of second couplers via the plurality of first output arms of the first coupler, two or more intermediate waveguides of the plurality of intermediate waveguides, and respective second input arms of the plurality of second couplers, and each second coupler is connected to two or more output waveguides, of the plurality of output waveguides, via the plurality of second output arms of the second coupler.

In some implementations, a multicore fiber amplifier comprising: a laser redundancy device that includes: a plurality of lasers; and a PLC that includes a plurality of input waveguides, a plurality of first couplers, a plurality of intermediate waveguides, a plurality of second couplers, and a plurality of output waveguides, wherein: each first coupler is connected to: two or more input waveguides, of the plurality of input waveguides, via a plurality of first input arms of the first coupler, and the plurality of second couplers via a plurality of first output arms of the first coupler, two or more intermediate waveguides of the plurality of intermediate waveguides, and respective second input arms of the plurality of second couplers, and each second coupler is connected to two or more output waveguides, of the plurality of output waveguides, via a plurality of second output arms of the second coupler.

In some implementations, a co-packaged optics (CPO) transmission source comprising: a laser redundancy device that includes: a plurality of lasers; and a PLC that includes a plurality of input waveguides, a plurality of first couplers, a plurality of intermediate waveguides, a plurality of second couplers, and a plurality of output waveguides, wherein: each first coupler is connected to: two or more input waveguides of the plurality of input waveguides, and the plurality of second couplers via two or more intermediate waveguides of the plurality of intermediate waveguides, and each second coupler is connected to two or more output waveguides of the plurality of output waveguides.

### BRIEF DESCRIPTION OF THE DRAWINGS

FIG. 1 is a diagram of an example implementation described herein.

FIGS. 2A-2B are diagrams of an example implementation described herein.

FIG. 3 is a diagram of an example implementation described herein.

FIG. 4 is a diagram of an example implementation described herein.

### DETAILED DESCRIPTION

The following detailed description of example implementations refers to the accompanying drawings. The same reference numbers in different drawings may identify the same or similar elements.

An optical system (e.g., an optical amplifier or another type of optical system) can require that multiple laser beams be provided within the optical system. In many cases, multiple lasers provide the multiple laser beams via respective optical channels. This typically requires that a large quantity of discrete components (e.g., waveguides, optical isolators, lenses, or other components) be used per optical channel (and per laser) to ensure that a laser beam is provided within the optical system as intended. Including these numerous components requires a substantial physical area (e.g., in terms of area and/or volume), which can increase design complexity when trying to package the components as part of the optical system. Further, in some cases, an individual laser may cease to function and therefore no longer provide a laser beam within the optical system, which can negatively affect a performance of the optical system, or can cause the optical system to cease functioning as intended.

Some implementations described herein include a laser redundancy device. The laser redundancy device includes a plurality of lasers and a PLC that includes a plurality of input waveguides, a plurality of first couplers, a plurality of intermediate waveguides, a plurality of second couplers, and a plurality of output waveguides. Each first coupler includes a plurality of first input arms and a plurality of first output arms. Each second coupler includes a plurality of second input arms and a plurality of second output arms. Each first coupler is connected to two or more input waveguides via the plurality of first input arms, and the plurality of second couplers via the plurality of first output arms, two or more intermediate waveguides, and respective second input arms of the plurality of second couplers. Each second coupler is connected to two or more output waveguides via the plurality of second output arms.

Accordingly, the plurality of lasers are configured to couple a plurality of laser beams into the PLC (e.g., into the plurality of input waveguides of the PLC). The PLC (e.g., by using the plurality of input waveguides, the plurality of first couplers, the plurality of intermediate waveguides, the plurality of second couplers, and the plurality of output waveguides to propagate and combine portions of the plurality of laser beams) is configured to provide (e.g., as an output of the PLC) a plurality of output laser beams, wherein each output laser beam includes at least a portion of each laser beam of the plurality of laser beams. In this way, even when one or more of the lasers fail to provide laser beams, the PLC still provides a same number of output laser beams (where each output laser beam includes portions of laser beams that are provided by operational lasers). This can improve a performance of an optical system (e.g., a multicore fiber amplifier, a CPO transmission source, or another type of optical system) that includes the laser redundancy device. Further, in some cases, this allow the optical system to continue functioning as intended (e.g., even when one or more lasers are not operating).

In some implementations, because the laser redundancy device includes only the laser array, the PLC, and an optional optical component (e.g., that is configured to facilitate coupling of laser beams into the PLC), other components do not need to be used. Accordingly, a physical area of the laser redundancy device can be less than that of utilizing individual lasers with discrete components. This allows the laser redundancy device to be used in a compact package for an optical system (e.g., where a multi-component configuration could not otherwise be used). Further, because the laser redundancy device is a single device, a design complexity associated with including the laser redundancy device within an optical system is reduced (e.g., as compared to a multi-component configuration).

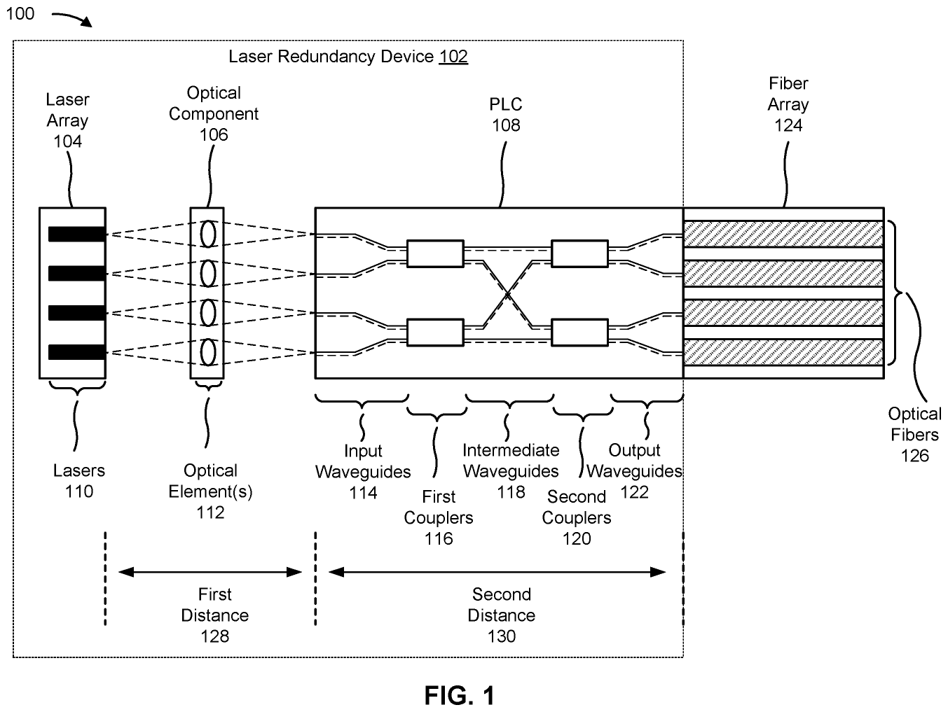

FIG. 1 is a diagram of an example implementation 100 described herein. FIG. 1 shows a schematic view of a laser redundancy device 102. As shown in FIG. 1, the laser redundancy device 102 may include a laser array 104, an optical component 106, and/or a PLC 108.

The laser array 104 may include a plurality of lasers 110 (shown as black rectangles). Each laser 110 may be, for example, a vertical-cavity surface-emitting laser (VCSEL), an edge-emitting laser (EEL), or another type of laser, that is disposed on a substrate (e.g., a common substrate). Each laser 110 may be configured to emit a laser beam (e.g., that is destined to be coupled into the PLC 108). The plurality of lasers 110 may be arranged in a one-dimensional array within the laser array 104 (e.g., on the substrate). The plurality of lasers 110 may be arranged in the one-dimensional array such that that plurality of lasers 110 are configured to emit a plurality of laser beams (e.g., from an emitting end of the laser array 104) in a same direction (e.g., a right-ward direction, as shown in FIG. 1).

The optical component 106 may include one or more optical elements 112 (shown as ovals). Each optical element 112 may include, for example, a lens (e.g., a focusing lens), a reflective element, a refractive element, and/or another type of optical element, and may be configured to receive at least one laser beam (e.g., from at least one laser 110 of the laser array 104) and to direct the at least one laser beam in a particular direction (e.g., a right-ward direction, as shown in FIG. 1). The optical component 106 may be positioned, relative to the laser array 104, such that that the one or more optical elements 112 are positioned to receive a plurality of laser beams emitted by the plurality of lasers 110. That is, the optical component 106 may be positioned such that that the one or more optical elements 112 are positioned within optical paths of the plurality of laser beams.

The PLC 108 may include a plurality of input waveguides 114, a plurality of first couplers 116, a plurality of intermediate waveguides 118, a plurality of second couplers 120, and/or a plurality of output waveguides 122. Each waveguide, of the plurality of input waveguides 114, the plurality of intermediate waveguides 118, and the plurality of output waveguides 122 (shown as solid black lines) may include a structure, channel, or other optical element, that is configured to propagate a laser beam (e.g., to guide and control propagation of the laser beam from an “input” end of the waveguide to an “output” end of the waveguide).

Each coupler of the plurality of first couplers 116 and the plurality of second couplers 120 (shown as white rectangles with a black border) may include a multimode interference coupler (MMI), a directional coupler, or another type of coupler. Moreover, each coupler may include a plurality of input arms and a plurality of output arms. For example, as shown in FIG. 1, each coupler may be a 2×2 coupler (e.g., that includes two input arms and two output arms). Each coupler may be configured to receive a plurality of light beams (e.g., that are received by the coupler via the plurality of input arms of the coupler), to combine the plurality of light beams into a combined laser beam, and to provide portions of the combined laser beam (e.g., via the plurality of output arms of the coupler). Each coupler may be configured to have a fixed split ratio (e.g., each output arm of the coupler may provide a particular percentage of the combined laser beam), or, alternatively, a tunable split ratio (e.g., each output arm may be “tuned,” such as by a user tasked to operate, maintain, and/or service the laser redundancy device 102, to provide a particular percentage of the combined laser beam). In this way, each coupler may be configured to facilitate precise combination of laser beams, such as to enable equalizing power levels of the laser beams or forming specific power ratios among the laser beams.

As shown in FIG. 1, each input waveguide 114 may be positioned at an input end of the PLC 108 (e.g., the left side of the PLC 108, as shown in FIG. 1) and may be connected to an input arm of a first coupler 116 of the plurality of the first couplers 116. Accordingly, each input waveguide 114 may be configured to receive a laser beam (e.g., that is emitted by a laser 110 of the laser array 104, and which may be directed to the input waveguide 114 by an optical element 112 of the optical component 106), and may be configured to propagate the laser beam to an input arm of a first coupler 116 that is connected to the input waveguide 114.

Each first coupler 116 may be connected, via a plurality of input arms of the first coupler 116, to two or more input waveguides 114 (of the plurality of input waveguides 114), and may be connected, via a plurality of output arms of the first coupler 116, to two or more intermediate waveguides 118 (of the plurality of intermediate waveguides 118). For example, as shown in FIG. 1, each first coupler 116 (e.g., that is a 2×2 coupler) may be connected to two input waveguides 114 and two intermediate waveguides 118. Accordingly, each first coupler 116 may be configured to receive (e.g., respectively receive) a plurality of laser beams from the two or more input waveguides 114; to combine the plurality of laser beams into a combined laser beam; and to provide (e.g., respectively provide) portions of the combined laser beam to the two or more intermediate waveguides 118.

As shown in FIG. 1, each intermediate waveguide 118 may be positioned at an internal region of the PLC 108 (e.g., a central, non-perimeter, region of the PLC 108, as shown in FIG. 1), and may be connected to an output arm of a first coupler 116 (of the plurality of the first couplers 116) and to an input arm of a second coupler 120 (of the plurality of second couplers 120). Accordingly, each intermediate waveguide 118 may be configured to receive portion of a combined laser beam (e.g., that is provided to the intermediate waveguide 118 by a first coupler 116 via an output arm of the first coupler 116), and may be configured to propagate the portion of the combined laser beam to an input arm of a second coupler 120 that is connected to the intermediate waveguide 118.

Each second coupler 120 may be connected, via a plurality of input arms of the second coupler 120, to two or more intermediate waveguides 118 (of the plurality of intermediate waveguides 118), and may be connected, via a plurality of output arms of the second coupler 120, to two or more output waveguides 122 (of the plurality of output waveguides 122). For example, as shown in FIG. 1, each second coupler 120 (e.g., that is a 2×2 coupler) may be connected to two intermediate waveguides 118 and two output waveguides 122. Further, each input arm (of the plurality of input arms) of the second coupler 120 may be connected to a particular first coupler 116 (of the plurality of first couplers 116), such as to an output arm (of a plurality of output arms) of the particular first coupler 116, via an intermediate waveguide 118. That is, the second coupler may be connected to two or more first couplers 116 (of the plurality of first couplers 116) via respective two or more intermediate waveguides 118 (of the plurality of intermediate waveguides 118). Accordingly, each second coupler 120 may be configured to receive (e.g., respectively receive) a plurality of portions of combined laser beams (e.g., portions of combined laser beams respectively combined by two or more first couplers 116) from two or more intermediate waveguides 118; to combine the plurality of portions of combined laser beams into an additionally combined laser beam; and to provide (e.g., respectively provide) portions of the additionally combined laser beam to two or more output waveguides 122.

As shown in FIG. 1, each output waveguide 122 may be positioned at an output end of the PLC 108 (e.g., the right side of the PLC 108, as shown in FIG. 1) and may be connected to an output arm of a second coupler 120 (of the plurality of the second couplers 120). Accordingly, each output waveguide 122 may be configured to receive a portion of an additionally combined laser beam (e.g., that is provided to the output waveguide 122 by a second coupler 120 via an output arm of the second coupler 120), and may be configured to propagate the portion of the additionally combined laser beam out of the PLC 108 (e.g., via the output end of the PLC 108). Accordingly, each portion of an additionally combined laser beam may be referred to as an output laser beam elsewhere herein.

FIG. 1 further shows example propagation paths (indicated by dashed black lines) of laser beams (and portions of laser beams) through the laser redundancy device 102. The plurality of lasers 110 may emit a plurality laser beams (four laser beams, as shown in FIG. 1), which may propagate, via the one or more optical elements 112 of the optical component 106, to the plurality of input waveguides 114 of the PLC 108. In this way, the plurality of lasers 110 may be configured to couple the plurality of laser beams into the plurality of input waveguides 114 (e.g., each laser 110 may be configured to couple a laser beam into a corresponding input waveguide 114).

The plurality of input waveguides 114 may be configured to propagate the plurality of laser beams to the plurality of first couplers 116. For example, as shown in FIG. 1, a first group of input waveguides 114 (e.g., the top two input waveguides 114) may be configured to propagate a first group of laser beams (e.g., two laser beams emitted by the top two lasers 110) to a first of the first couplers 116 (e.g. the top first coupler 116), and a second group of input waveguides 114 (e.g., the bottom two input waveguides 114) may be configured to propagate a second group of laser beams (e.g., two laser beams emitted by the bottom two lasers 110) to a second of the first couplers 116 (e.g. the bottom first coupler 116).

Each first coupler 116 may be configured to combine the laser beams received by the first coupler 116 into a combined laser beam, and to provide portions of the combined laser beam to each of the plurality of second couplers 120 via corresponding intermediate waveguides 118. Accordingly, the plurality of intermediate waveguides 118 may be configured to propagate portions of combined laser beams to the plurality of second couplers 120. For example, the first of the first couplers 116 (e.g. the top first coupler 116) may be configured to combine the first group of laser beams into a first combined laser beam, and to provide a first portion of the first combined laser beam to a first of the second couplers 120 (e.g., the top second coupler 120) via a first intermediate waveguide 118 (e.g., that is connected to the top first coupler 116 and to the top second coupler 120) and a second portion of the first combined laser beam to a second of the second couplers 120 (e.g., the bottom second coupler 120) via a second intermediate waveguide 118 (e.g., that is connected to the top first coupler 116 and to the bottom second coupler 120). As an additional example, the second of the first couplers 116 (e.g. the bottom first coupler 116) may be configured to combine the second group of laser beams into a second combined laser beam, and to provide a first portion of the second combined laser beam to the first of the second couplers 120 (e.g., the top second coupler 120) via a third intermediate waveguide 118 (e.g., that is connected to the bottom first coupler 116 and to the top second coupler 120) and a second portion of the second combined laser beam to the second of the second couplers 120 (e.g., the bottom second coupler 120) via a fourth intermediate waveguide 118 (e.g., that is connected to the bottom first coupler 116 and to the bottom second coupler 120).

Each second coupler 120 may be configured to combine portions of combined laser beams received by the second coupler 120 into an additionally combined laser beam, and to provide portions of the additionally combined laser beam for output (e.g., out of the PLC 108) via corresponding output waveguides 122. Accordingly, the plurality of output waveguides 122 may be configured to propagate portions of additionally combined laser beams out of the PLC 108.

For example, the first of the second couplers 120 (e.g., the top second coupler 120) may be configured to combine the first portion of the first combined laser beam and the first portion of the second combined laser beam into a first additionally combined laser beam, and to provide a first portion of the first additionally combined laser beam for output via a first output waveguide 122 (e.g., that is connected to the top second coupler 120) and a second portion of the first additionally combined laser beam for output via a second output waveguide 122 (e.g., that is connected to the top second coupler 120). As an additional example, the second of the second couplers 120 (e.g., the bottom second coupler 120) may be configured to combine the second portion of the first combined laser beam and the second portion of the second combined laser beam into a second additionally combined laser beam, and to provide a first portion of the second additionally combined laser beam for output via a third output waveguide 122 (e.g., that is connected to the bottom second coupler 120) and a second portion of the second additionally combined laser beam for output via a fourth output waveguide 122 (e.g., that is connected to the bottom second coupler 120).

In this way, each of the portions of the additionally combined laser beams (e.g., each output laser beam) may comprise at least a portion of each laser beam that is emitted by the plurality of lasers 110. For example, when each of the couplers of the plurality of first couplers 116 and the second couplers 120 have an equal split ratio (e.g., a “50/50” split ratio for 2×2 couplers shown in FIG. 1), each portion of an additionally combined laser beam (also referred to as an output laser beam) that is output via the plurality of output waveguides 122 may include an equal amount (or nearly equal amount) of each laser beam of the plurality of laser beams emitted by the plurality of lasers 110. Accordingly, if a particular laser 110 were to encounter a performance issue and cease emitting a laser beam, each output laser beam would include a combination of other laser beams, of the plurality of beams, that are still emitted by other lasers 110 of the plurality of lasers 110.

As further shown in FIG. 1, the laser redundancy device 102 may be configured to connect to a fiber array 124. For example, an output end of the laser redundancy device 102 (e.g., that includes the output end of the PLC 108) may be configured to connect to an input end of the fiber array 124.

The fiber array 124 may include a plurality of optical fibers 126 (shown as rectangles with diagonal patterning). Each optical fiber 126 may include, for example, a core, and, optionally, one or more claddings. Each optical fiber 126 may be configured to propagate an output laser beam (e.g., away from the laser redundancy device 102), such as via the core of the optical fiber 126. The plurality of optical fibers 126 may be arranged in a one-dimensional array within the fiber array 124.

In some implementations, the laser redundancy device 102 may be configured to connect to the fiber array 124 such that the plurality of output waveguides 122 of the PLC 108 are aligned with the plurality of optical fibers 126 of the fiber array 124. That is, the laser redundancy device 102 may be configured to connect to the fiber array 124 to allow output laser beams provided by the laser redundancy device 102 (e.g., via the plurality of output waveguides 122 of the PLC 108) to couple into corresponding optical fibers 126 of the fiber array 124 (e.g., to couple into the respective cores of the corresponding optical fibers 126).

In some implementations, the laser redundancy device 102 may be configured to have a first distance 128 that is measured from the emitting end of the laser array 104 to the input end of the PLC 108. The first distance 128 may be, for example, between 3 and 5 millimeters (mm) (e.g., greater than or equal to 3 mm and less than 5 mm), such as for a “compact” design, or between 5 and 20 mm, such as for a “non-compact” design. The first distance 128 may allow the optical component 106 to be positioned between the laser array 104 and the PLC 108, and to allow the one or more optical elements 112 to receive a plurality of laser beams emitted by the plurality of lasers 110, and to direct the plurality of laser beams to the plurality of input waveguides 114 of the PLC 108 (e.g., to allow the plurality of laser beams to couple into the plurality of input waveguides 114). Additionally, the laser redundancy device 102 may be configured to have a second distance 130 that is measured from the input end of the PLC 108 to the output end of the PLC 108 (e.g., a length of the PLC 108). The second distance 130 may be, for example, between 3 and 5 mm, such as for a compact design, or between 6 and 20 mm, such as for a non-compact design. The second distance 130 may facilitate combination of the plurality of laser beams, as described herein.

As indicated above, FIG. 1 is provided as an example. Other examples may differ from what is described with regard to FIG. 1. The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more functions described as being performed by another set of components shown in FIG. 1.

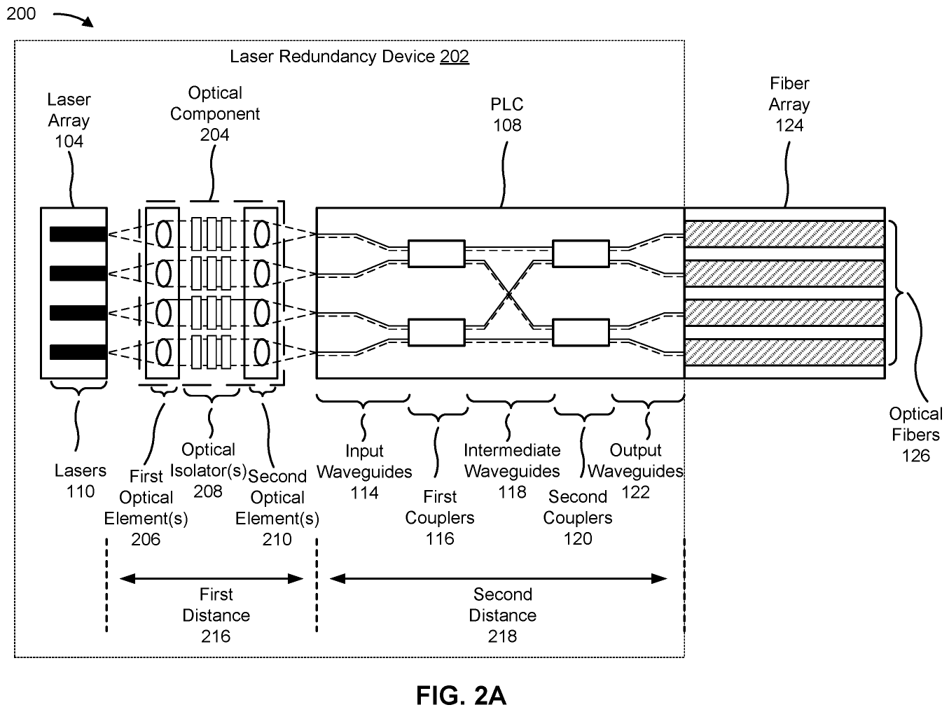

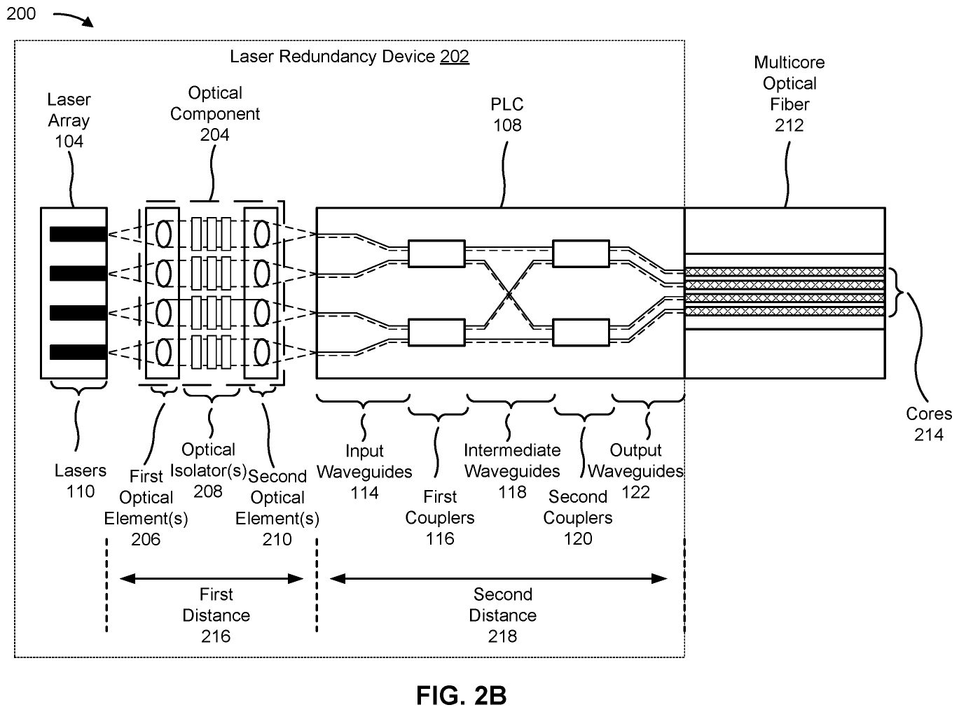

FIGS. 2A-2B are diagrams of an example implementation 200 described herein. FIGS. 2A-2B show schematic views of a laser redundancy device 202. As shown in FIGS. 2A-2B, the laser redundancy device 202 may include the laser array 104 (e.g., that includes the plurality of lasers 110) and the PLC 108 (e.g., that includes the plurality of input waveguides 114, the plurality of first couplers 116, the plurality of intermediate waveguides 118, the plurality of second couplers 120, and/or the plurality of output waveguides 122) described herein in relation to FIG. 1. The laser redundancy device 202 may also include an optical component 204 (e.g., instead of an optical component 106), which may include one or more first optical elements 206, one or more optical isolators 208, and/or a one or more second optical elements 210.

Each first optical element 206 may include, for example, a lens (e.g., a collimating lens), a reflective element, a refractive element, and/or another type of optical element, and may be configured to receive at least one laser beam (e.g., from at least one laser 110 of the laser array 104) and to direct the at least one laser beam in a particular direction (e.g., a right-ward direction, as shown in FIGS. 2A-2B), such as to a corresponding optical isolator 208. Each optical isolator 208 may include, for example, a Faraday rotator and a plurality of birefringent crystal plates, and may be configured to receive at least one laser beam (e.g., from a first optical element 206), may be configured to direct the at least one laser beam in the particular direction (e.g., the right-ward direction, as shown in FIGS. 2A-2B), such as to a corresponding second optical element 210. Additionally, the optical isolator 208 may be configured to prevent (or minimize) back reflection of the at least one laser beam (e.g., to at least one laser 110 that emitted the at least one laser beam, which protects the at least one laser 110 from an impaired performance). Each second optical element 210 may include, for example, a lens (e.g., a focusing lens), a reflective element, a refractive element, and/or another type of optical element, and may be configured to receive at least one laser beam (e.g., from an optical isolator 208) and to direct the at least one laser beam in the particular direction (e.g., the right-ward direction, as shown in FIGS. 2A-2B), such as to a corresponding input waveguide 114 of the PLC 108.

FIGS. 2A-2B further show example propagation paths (indicated by dashed lines) of laser beams (and portions of laser beams) through the laser redundancy device 202. Accordingly, as shown in FIGS. 2A-2B, the optical component 204 may be positioned, relative to the laser array 104, such that that the one or more first optical elements 206 are positioned to receive a plurality of laser beams emitted by the plurality of lasers 110. That is, the optical component 106 may be positioned such that that the one or more first optical elements 206 are positioned within optical paths of the plurality of laser beams. The plurality of laser beams may therefore propagate, via the one or more first optical elements 206, the one or more optical isolators 208, and/or the one or more second optical elements 210 of the optical component 204, to the plurality of input waveguides 114 of the PLC 108. In this way, the plurality of lasers 110 may be configured to couple the plurality of laser beams into the plurality of input waveguides 114 (e.g., each laser 110 may be configured to couple a laser beam into a corresponding input waveguide 114). The plurality of laser beams then may be propagated and may be combined by the PLC 108 (e.g., by the plurality of input waveguides 114, the plurality of first couplers 116, the plurality of intermediate waveguides 118, the plurality of second couplers 120, and/or the plurality of output waveguides 122 of the PLC 108), in a similar manner as that described herein in relation to FIG. 1. The PLC 108 may thereby provide a plurality of output laser beams (e.g., that each comprise at least a portion of each laser beam that is emitted by the plurality of lasers 110).

As further shown in FIG. 2A, the laser redundancy device 202 may be configured to connect to the fiber array 124. For example, an output end of the laser redundancy device 202 (e.g., that includes the output end of the PLC 108) may be configured to connect to the input end of the fiber array 124, such as in a manner that is similar to that described herein in relation to FIG. 1.

Alternatively, as shown in FIG. 2B, the laser redundancy device 202 may be configured to connect to a multicore optical fiber 212. The multicore optical fiber 212 may include a plurality of cores 214 (shown as rectangles with diamond patterning). Each core 214 may be configured to propagate an output laser beam (e.g., away from the laser redundancy device 102). The plurality of cores 214 may be arranged in a one-dimensional array (e.g., a vertical array, as shown in FIG. 1) within the multicore optical fiber 212.

In some implementations, the output end of the laser redundancy device 202 (e.g., that includes the output end of the PLC 108) may be configured to connect to an input end of the multicore optical fiber 212. In this way, the laser redundancy device 202 may be configured to connect to the multicore optical fiber 212 such that the plurality of output waveguides 122 of the PLC 108 are aligned with the plurality of cores 214 of the multicore optical fiber 212. That is, the laser redundancy device 202 may be configured to connect to the fiber array 124 to allow output laser beams provided by the laser redundancy device 202 (e.g., via the plurality of output waveguides 122 of the PLC 108) to couple into corresponding cores 214 of the multicore optical fiber 212.

In some implementations, the laser redundancy device 102 may be configured to have a first distance 216 that is measured from the emitting end of the laser array 104 to the input end of the PLC 108. The first distance 128 may be, for example, between 5 and 6 mm, such as for a compact design, or between 6 and 20 mm, such as for a non-compact design. The first distance 216 may allow the optical component 204 to be positioned between the laser array 104 and the PLC 108, and to allow the optical component 204 to receive a plurality of laser beams emitted by the plurality of lasers 110, and to direct the plurality of laser beams to the plurality of input waveguides 114 of the PLC 108 (e.g., to allow the plurality of laser beams to couple into the plurality of input waveguides 114). Additionally, the laser redundancy device 102 may be configured to have a second distance 218 that is measured from the input end of the PLC 108 to the output end of the PLC 108 (e.g., a length of the PLC 108). The second distance 218 may be, for example, between 3 and 5 mm, such as for a compact design, or between 6 and 20 mm, such as for a non-compact design. The second distance 218 may facilitate combination of the plurality of laser beams, as described herein.

As indicated above, FIGS. 2A-2B are provided as an example. Other examples may differ from what is described with regard to FIGS. 2A-2B. The number and arrangement of components shown in FIGS. 2A-2B are provided as an example. In practice, there may be additional components, fewer components, different components, or differently arranged components than those shown in FIGS. 2A-2B. Furthermore, two or more components shown in FIGS. 2A-2B may be implemented within a single component, or a single component shown in FIGS. 2A-2B may be implemented as multiple, distributed components. Additionally, or alternatively, a set of components (e.g., one or more components) shown in FIGS. 2A-2B may perform one or more functions described as being performed by another set of components shown in FIGS. 2A-2B.

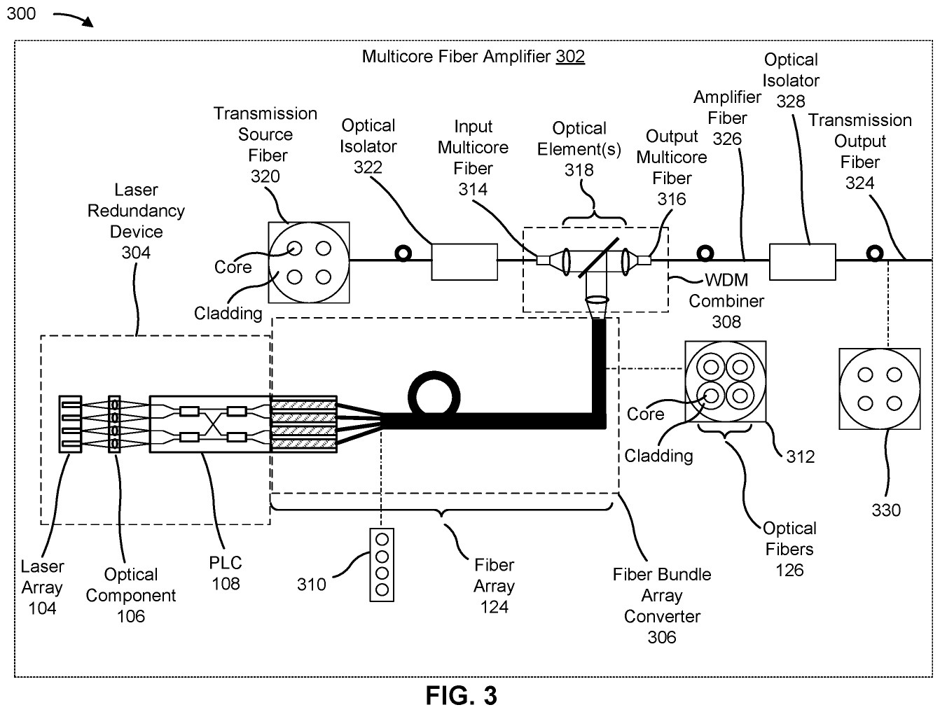

FIG. 3 is a diagram of an example implementation 300 described herein. FIG. 3 shows a schematic view of a multicore fiber amplifier 302. As shown in FIG. 3, the multicore fiber amplifier 302 may include a laser redundancy device 304, a fiber bundle array converter 306, and/or a wavelength division multiplexing (WDM) combiner 308.

The laser redundancy device 304 may be the same as, or similar to, the laser redundancy device 102 and/or the laser redundancy device 202 described herein in relation to FIGS. 1 and 2A-2B. For example, as shown in FIG. 3, the laser redundancy device 304 may include the laser array 104 (e.g., that includes the plurality of lasers 110), the optical component 106 (e.g., that includes the one or more optical elements 112), and the PLC 108 (e.g., that includes the plurality of input waveguides 114, the plurality of first couplers 116, the plurality of intermediate waveguides 118, the plurality of second couplers 120, and/or the plurality of output waveguides 122) described herein in relation to FIGS. 1 and 2A-2B.

The fiber bundle array converter 306 may include the fiber array 124 (e.g., that is described herein in relation FIGS. 1 and 2A-2B). Accordingly, the laser redundancy device 304 may be configured to connect to the fiber array 124, such as in a similar manner as that described herein in relation to FIGS. 1 and 2A-2B. For example, an output end of the laser redundancy device 304 (e.g., that includes the output end of the PLC 108) may be configured to connect to the input end of the fiber array 124 (e.g., that is also an input end of the fiber bundle array converter 306), which may allow a plurality of output laser beams provided by the laser redundancy device 304 (e.g., via the plurality of output waveguides 122 of the PLC 108) to couple into corresponding optical fibers 126 of the fiber array 124 (e.g., to couple into the respective cores of the corresponding optical fibers 126).

Accordingly, because the plurality of optical fibers 126 may be arranged in a one-dimensional array within the fiber array 124 at the input end of the fiber array 124, the plurality of output laser beams may couple into the optical fibers 126 of the fiber array 124 in a one-dimensional array as shown in FIG. 3, and by reference number 310. Additionally, as further shown in FIG. 3, and by reference number 312, the plurality of optical fibers 126 of the fiber array 124 may be arranged, at an output end of the fiber array 124 (e.g., that is also an output end of the fiber bundle array converter 306), in a two-dimensional array (e.g., a 2×2 array, where each optical fiber 126 includes a core and a cladding). Accordingly, the plurality of output laser beams may be arranged in a two-dimensional array (shown as a 2×2 array) at the output end of the fiber array 124, and may thereby propagate to the WDM combiner 308 (e.g., in the two-dimensional array arrangement).

The WDM combiner 308 may include an input multicore fiber 314, an output multicore fiber 316, and/or one or more optical elements 318. The input multicore fiber 314 may be configured to receive (e.g., via a plurality of cores of the input multicore fiber 314 that are arranged in a two-dimensional array) a plurality of transmission laser beams (e.g., that may be “signal” laser beams) from a transmission source fiber 320. For example, the transmission source fiber 320 may be a multicore optical fiber that includes a plurality of cores (e.g., in a common cladding) that are arranged in a two-dimensional array (shown as a 2×2 array), and therefore the plurality of transmission laser beams may propagate (e.g., via an optical isolator 322) to the input multicore fiber 314 in a two-dimensional array arrangement. The input multicore fiber 314 may be further configured to propagate the plurality of transmission laser beams to the one or more optical elements 318.

The one or more optical elements 318 may include, for example, one or more lenses, one or more reflective elements, one or more refractive elements, one or more filters, and one or more other types of optical elements, and may be configured to receive the plurality of output laser beams from the fiber bundle array converter 306 and the plurality of transmission laser beams from the input multicore fiber 314; to combine the plurality of output laser beams and the plurality of transmission laser beams (e.g., using a WDM technique) into a plurality of multiplexed laser beams; and provide the plurality of multiplexed laser beams to the output multicore fiber 316.

The output multicore fiber 316 may be configured to receive and propagate the plurality of multiplexed laser beams from the one or more optical elements 318. For example, the output multicore fiber 316 may include a plurality of cores that are arranged in a two-dimensional array (e.g., as a 2×2 array), and therefore the plurality of multiplexed laser beams may propagate (via the output multicore fiber 316) in a two-dimensional array arrangement, such as to a transmission output fiber 324 (e.g., via a multicore amplifier fiber 326 and/or an optical isolator 328).

As shown by reference number 330, the transmission output fiber 324 may be a multicore optical fiber that includes a plurality of cores (e.g., in a common cladding) that are arranged in a two-dimensional array (shown as a 2×2 array), and therefore the plurality of multiplexed laser beams may couple into the transmission output fiber 324 and may propagate via the transmission output fiber 324 in a two-dimensional array arrangement (e.g., to an output end of the transmission output fiber 324).

As indicated above, FIG. 3 is provided as an example. Other examples may differ from what is described with regard to FIG. 3. For example, the fiber bundle array converter 306 may have the multicore fiber 212 (e.g., as shown in FIG. 2B) as an input, and an output may be a two-dimensional array (e.g., 2×2) in a multicore fiber (e.g., similar to the transmission source fiber 320 or the transmission output fiber 324).

The number and arrangement of components shown in FIG. 3 are provided as an example. In practice, there may be additional components, fewer components, different components, or differently arranged components than those shown in FIG. 3. Furthermore, two or more components shown in FIG. 3 may be implemented within a single component, or a single component shown in FIG. 3 may be implemented as multiple, distributed components. Additionally, or alternatively, a set of components (e.g., one or more components) shown in FIG. 3 may perform one or more functions described as being performed by another set of components shown in FIG. 3.

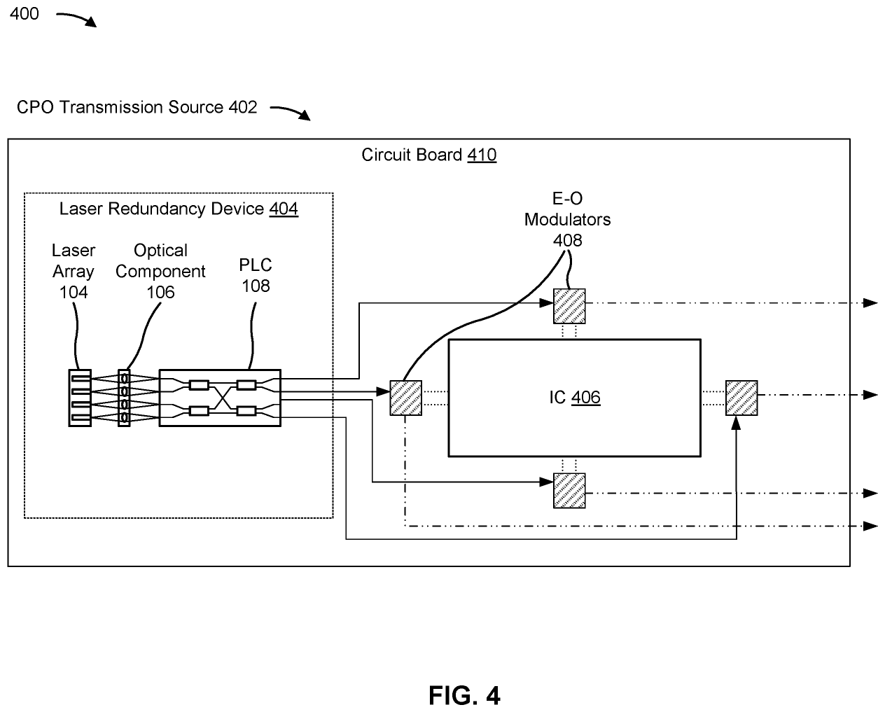

FIG. 4 is a diagram of an example implementation 400 described herein. FIG. 4 shows a schematic view of a co-packaged optics (CPO) transmission source 402 (e.g., that is configured to facilitate optical communications). As shown in FIG. 4, the CPO transmission source 402 may include a laser redundancy device 404, an integrated circuit (IC) 406, and a plurality of electro-optical (E-O) modulators 408, each of which may be disposed on and/or integrated into a circuit board 410 (e.g., printed circuit board (PCB)) of the CPO transmission source 402. Alternatively, the plurality of E-O modulators 408 may be disposed on or integrated in the IC 406.

The laser redundancy device 404 may be the same as, or similar to, the laser redundancy device 102 and/or the laser redundancy device 202 described herein in relation to FIGS. 1 and 2A-2B. For example, as shown in FIG. 4, the laser redundancy device 404 may include the laser array 104 (e.g., that includes the plurality of lasers 110), the optical component 106 (e.g., that includes the one or more optical elements 112), and the PLC 108 (e.g., that includes the plurality of input waveguides 114, the plurality of first couplers 116, the plurality of intermediate waveguides 118, the plurality of second couplers 120, and/or the plurality of output waveguides 122) described herein in relation to FIGS. 1 and 2A-2B.

The laser redundancy device 404 may be configured to connect to the plurality of E-O modulators 408. For example, the laser redundancy device 404 may be configured to connect to the plurality of E-O modulators 408 such that the plurality of output waveguides 122 of the PLC 108 are aligned with, or linked to, the plurality of E-O modulators 408. That is, the laser redundancy device 404 may be configured to connect to the plurality of E-O modulators 408 to allow output laser beams provided by the laser redundancy device 404 (e.g., via the plurality of output waveguides 122 of the PLC 108) to couple into corresponding E-O modulators 408.

Each E-O modulator 408 (shown in FIG. 4 as rectangles with diagonal patterning) may be configured to modify one or more properties of an output laser beam (e.g., that is provided to the E-O modulator 408 by an output waveguide 122 of the PLC 108 of the laser redundancy device 404). For example, each E-O modulator 408 may be a silicon photonic device that is configured to modify an intensity, a phase, a polarization, and/or another property, of an output laser beam, such as in response to an electrical signal (e.g., an applied electrical voltage) that is provided by the IC 406.

The IC 406 may be a field programmable gate array (FPGA) chip, an application specific integrated circuit (ASIC) chip, a central processing unit (CPU), an electronic switch, or another type of chip. The IC 406 may be configured to (e.g., may include a driver circuit) to generate and/or provide an electrical signal (e.g., shown as dotted lines) to each of the plurality of E-O modulators 408. In this way, the IC 406 may be configured to control the plurality of E-O modulators 408 to cause respective properties of the plurality of output laser beams to be modified.

FIG. 4 further shows example propagation paths (indicated by arrows) of output laser beams through the CPO transmission source 402. The plurality of output laser beams (shown as arrows with solid black lines) may be provided by the laser redundancy device 404 to the plurality of E-O modulators 408. Accordingly, the IC 406 may control (e.g., by providing electrical signals to the plurality of E-O modulators 408) the plurality of E-O modulators 408 to modify respective properties of the plurality of output laser beams. The E-O modulators 408 may thereby respectively provide a plurality of modified output laser beams (shown as arrows with dashed and dotted black lines), such as for output from an output end of the circuit board 410, which may be an output end of the CPO transmission source 402.

Accordingly, as described in connection to FIGS. 1, 2A, and 2B, the laser redundancy device 404 (e.g., via the plurality of output waveguides 122 of the PLC 108) may be configured to couple a plurality of output laser beams into each of the E-O modulators 408, wherein each output laser beam includes at least a portion of a laser beam emitted by each of the plurality of laser beams 110 of the laser array 104. In this way, even when one or more of the lasers 110 fail to provide laser beams, the PLC 108 may still provide a same number of output laser beams (where each output laser beam includes portions of laser beams that are provided by operational lasers 110).

As indicated above, FIG. 4 is provided as an example. Other examples may differ from what is described with regard to FIG. 4. The number and arrangement of components shown in FIG. 4 are provided as an example. In practice, there may be additional components, fewer components, different components, or differently arranged components than those shown in FIG. 4. Furthermore, two or more components shown in FIG. 4 may be implemented within a single component, or a single component shown in FIG. 4 may be implemented as multiple, distributed components. Additionally, or alternatively, a set of components (e.g., one or more components) shown in FIG. 4 may perform one or more functions described as being performed by another set of components shown in FIG. 4.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” “left,” “right,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A laser redundancy device comprising:
a plurality of lasers disposed on a common substrate; and
a planar lightwave circuit (PLC) that includes a plurality of input waveguides, a plurality of first couplers, a plurality of intermediate waveguides, a plurality of second couplers, and a plurality of output waveguides, wherein:
each first coupler, of the plurality of first couplers, includes a plurality of first input arms and a plurality of first output arms,
each second coupler, of the plurality of second couplers, includes a plurality of second input arms and a plurality of second output arms,
each first coupler is connected to:
two or more input waveguides, of the plurality of input waveguides, via the plurality of first input arms of the first coupler, and
the plurality of second couplers via the plurality of first output arms of the first coupler, two or more intermediate waveguides of the plurality of intermediate waveguides, and respective second input arms of the plurality of second couplers, and
each second coupler is connected to two or more output waveguides, of the plurality of output waveguides, via the plurality of second output arms of the second coupler.

2. The laser redundancy device of claim 1, wherein:
the plurality of lasers are configured to couple a plurality of laser beams into the plurality of input waveguides of the PLC; and
the plurality of output waveguides are configured to provide a plurality of output laser beams, wherein each output laser beam includes at least a portion of each laser beam of the plurality of laser beams.

3. The laser redundancy device of claim 1, further comprising:
an optical component that that includes one or more optical elements that are configured to facilitate the plurality of lasers coupling a plurality of laser beam into the plurality of input waveguides of the PLC.

4. The laser redundancy device of claim 3, wherein the optical component further includes one or more optical isolators.

5. The laser redundancy device of claim 1, wherein each coupler of the plurality of first couplers and the plurality of second couplers is configured to have a tunable split ratio.

6. The laser redundancy device of claim 1, wherein an output end of the laser redundancy device is configured to connect to an input end of a fiber array.

7. The laser redundancy device of claim 1, wherein an output end of the laser redundancy device is configured to connect to an input end of a multicore optical fiber.

8. A multicore fiber amplifier comprising:
a laser redundancy device that includes:
a plurality of lasers; and
a planar lightwave circuit (PLC) that includes a plurality of input waveguides, a plurality of first couplers, a plurality of intermediate waveguides, a plurality of second couplers, and a plurality of output waveguides, wherein:
each first coupler is connected to:
two or more input waveguides, of the plurality of input waveguides, via a plurality of first input arms of the first coupler, and
the plurality of second couplers via a plurality of first output arms of the first coupler, two or more intermediate waveguides of the plurality of intermediate waveguides, and respective second input arms of the plurality of second couplers, and
each second coupler is connected to two or more output waveguides, of the plurality of output waveguides, via a plurality of second output arms of the second coupler.

9. The multicore fiber amplifier of claim 8, wherein:
the plurality of input waveguides of the PLC are configured to receive a plurality of laser beams emitted by the plurality of lasers; and
the plurality of output waveguides of the PLC are configured to provide a plurality of output laser beams,
wherein each output laser beam includes at least a portion of each laser beam of the plurality of laser beams.

10. The multicore fiber amplifier of claim 8, further comprising:
a fiber bundle array converter; and
a wavelength division multiplexing (WDM) combiner.

11. The multicore fiber amplifier of claim 10, wherein an output end of the laser redundancy device is configured to connect to an input end of a fiber array of the fiber bundle array converter.

12. The multicore fiber amplifier of claim 8, wherein the laser redundancy device further includes:
an optical component that that includes one or more optical elements that are configured to facilitate coupling of a plurality of laser beam emitted by the plurality of lasers into the plurality of input waveguides of the PLC.

13. The multicore fiber amplifier of claim 12, wherein the optical component further includes one or more optical isolators.

14. The multicore fiber amplifier of claim 8, wherein each coupler of the plurality of first couplers and the plurality of second couplers is configured to have a tunable split ratio.

15. A co-packaged optics (CPO) transmission source comprising:
a laser redundancy device that includes:
a plurality of lasers; and
a planar lightwave circuit (PLC) that includes a plurality of input waveguides, a plurality of first couplers, a plurality of intermediate waveguides, a plurality of second couplers, and a plurality of output waveguides, wherein:
each first coupler is connected to:
two or more input waveguides of the plurality of input waveguides, and the plurality of second couplers via two or more intermediate waveguides of the plurality of intermediate waveguides, and
each second coupler is connected to two or more output waveguides of the plurality of output waveguides.

16. The CPO transmission source of claim 15, wherein:
the PLC is configured to receive a plurality of laser beams emitted by the plurality of lasers; and
the PLC is configured to provide a plurality of output laser beams,
wherein each output laser beam includes at least a portion of each laser beam of the plurality of laser beams.

17. The CPO transmission source of claim 15, further comprising:
an integrated circuit (IC); and
a plurality of electro-optical (E-O) modulators.

18. The CPO transmission source of claim 17, wherein the laser redundancy device is configured to connect to the plurality of E-O modulators.

19. The CPO transmission source of claim 15, wherein the laser redundancy device further includes:
an optical component that includes one or more optical elements.

20. The CPO transmission source of claim 15, wherein each coupler of the plurality of first couplers and the plurality of second couplers is configured to have a tunable split ratio.
